(19) United States
(12) Patent Application Publication
(10) Pub. No.: US 2022/0341585 A1
(43) Pub. Date: Oct. 27, 2022

(54) Electronic Devices With Backlit Partial Mirror Structures

(71) Applicant: Apple Inc., Cupertino, CA (US)

(72) Inventors: Patrick R. Perry, Boulder Creek, CA (US); Jun Cheng, Shanghai (CN); Martin Melcher, Paris (FR); Shravan Bharadwaj, San Jose, CA (US); Wanshan Li, Suzhou (CN); Scott M. Stryker, San Jose, CA (US)

(21) Appl. No.: 17/675,834

(22) Filed: Feb. 18, 2022

Related U.S. Application Data
(60) Provisional application No. 63/177,758, filed on Apr. 21, 2021.

(51) Int. Cl. F21V 33/00; G02B 5/08; F21V 8/00; G02B 5/28

(52) U.S. Cl. CPC F21V 33/004; G02B 5/0816; G02B 6/005; G02B 5/28; G02B 6/0088; F21Y 2115/10

(57) ABSTRACT

A backlit partially reflective mirror may be used to form a logo or other structure in an electronic device. The electronic device may have a housing. The housing may have a wall with one or more openings configured to receive one or more corresponding logo-shaped portions of the partially reflective mirror. The partially reflective mirror may be illuminated using backlight illumination from a backlight that is overlapped by the partially reflective mirror. The partially reflective mirror may be formed from one or more protruding structures on a common substrate. One or more thin-film layers may be configured to provide the partially reflective mirror with desired visible light reflection spectrum, a desired visible light transmission spectrum, and a desired visible light absorption spectrum. The reflectivity of the mirror may be configure so that the mirror serves as a one-way mirror for the logo or other structure.

This application claims the benefit of provisional patent application No. 63/177,758, filed Apr. 21, 2021, which is hereby incorporated by reference herein in its entirety.

### FIELD

This relates generally to electronic devices, and, more particularly, electronic devices with illuminated structures.

### BACKGROUND

Electronic devices such as may have housings formed from metal and other materials. In some arrangements, openings are formed in a housing to accommodate components. Openings may also be formed in the shapes of logos.

### SUMMARY

An electronic device such as a laptop computer or other device may have a housing. Components such as a display and keyboard may be mounted in the housing.

The rear of the hosing may be provided with a logo. The logo or other structures in the device may be provided with a backlit partially reflective mirror. The mirror may provide the logo or other structures with a shiny appearance while blocking interior components from view. At the same time, the partial transparency of the mirror allows backlight illumination from within the device to pass through the mirror.

The reflective mirror may be formed from one or more protruding structures on a common substrate. The protruding structures may be received within corresponding openings in a wall in the housing.

One or more thin-film layers may be configured to provide the partially reflective mirror with desired visible light reflection spectrum, a desired visible light transmission spectrum, and a desired visible light absorption spectrum. The reflectivity of the mirror may be configure so that the mirror serves as a one-way mirror for the logo or other structure. The mirror may have a neutral color such as light gray or may have a non-neutral color such as gold.

### BRIEF DESCRIPTION OF THE DRAWINGS

FIG. 1 is a side view of an illustrative electronic device with a backlit mirror structure in accordance with an embodiment.

FIG. 2 is a rear view of an illustrative housing with a backlit mirror structure having the shape of a two-part logo in accordance with an embodiment.

FIG. 3 is a graph showing illustrative reflection spectrums for mirror structures in accordance with embodiments.

FIG. 4 is a cross-sectional side view of an illustrative backlit mirror structure in accordance with an embodiment.

FIGS. 5, 6, and 7 are cross-sectional side views of illustrative backlights for mirror structures in accordance with embodiments.

FIGS. 8 and 9 are illustrative backlit mirrors in accordance with embodiments.

FIG. 10 is a perspective view of an illustrative keyboard key formed from a backlit mirror in accordance with an embodiment.

### DETAILED DESCRIPTION

An electronic device may have components mounted in a housing. The housing may be formed from glass, metal, polymer, ceramic, fiber-composite material, crystalline materials such as sapphire, other materials, and/or combinations of these materials. In an illustrative configuration, an electronic device housing may be formed from metal or other material with one or more openings to receive logo-shaped backlit partially reflective mirror structures. In general, any suitable portion of an electronic device may have a backlit mirror. Configurations in which the backlit mirror has a logo shape and is mounted in a housing wall opening are sometimes described herein as an example.

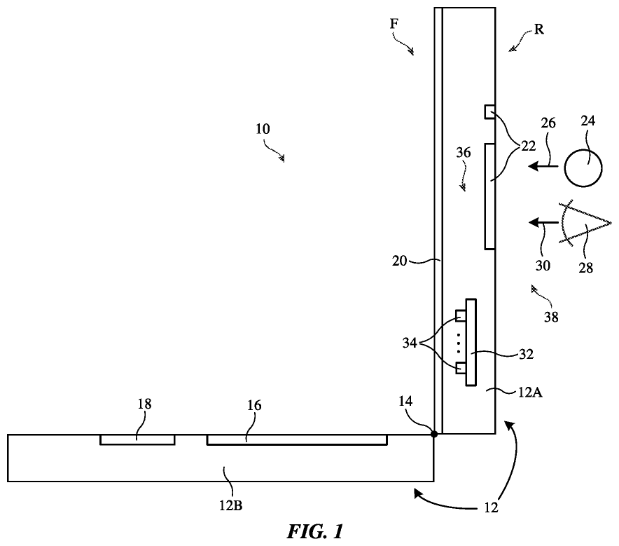

FIG. 1 is a cross-sectional view of an illustrative electronic device. Electronic device 10 of FIG. 1 may be a computing device such as a laptop computer, a computer monitor containing an embedded computer, a tablet computer, a cellular telephone, a media player, or other handheld or portable electronic device, a smaller device such as a wristwatch or other device worn on a user's wrist, a pendant device, a headphone or earpiece device, a head-mounted device such as eyeglasses, goggles, or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment. Illustrative configurations in which device 10 is a portable device such as a laptop computer may sometimes be described herein as an example.

As shown in FIG. 1, device 10 may include housing 12. Housing 12, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.).

In the example of FIG. 1, device 10 includes upper portion 12A (sometimes referred to as a display housing portion or lid) and lower portion 12B (sometime referred to as a base housing portion or base). Portions 12A and 12B may be coupled at hinge 14. Hinge 14 allows portions 12A and 12B to rotate relative to each other. This allows the lid of housing 12 to rotate relative to the base of housing 12 to open and close housing 12. Device 10 may be a laptop computer that includes keyboard 16 and trackpad 18 in base housing portion 12B and that includes display 20 in display housing portion 12A. Housing portion 12A may have a front F and an opposing rear R. Display 20 may be mounted on front F, so that display 20 is protected when portion 12A is rotated into a closed position and so that display 20 is visible to a user when portion 12A is open as shown in FIG. 1.

Housing 12 (including a display cover layer portion that covers display 20) may separate an interior region of device 10 such as interior region 36 from an exterior region surrounding device 10 such as exterior region 38. Components 34 may be mounted in housing 12 (e.g., components 34 may be mounted to one or more printed circuits 32 in interior region 36). Components 34 may include integrated circuits, discrete components, input-output devices such as sensors, trackpad 18, keyboard 16, display 20, etc.

Components 34 may include control circuitry. The control circuitry may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in the control circuitry may be used to control the operation of device 10. The processing circuitry may be based on one or more microprocessors, microcontrollers, digital signal processors, baseband processors, power management units, audio chips, application specific integrated circuits, etc. The control circuitry may include communications circuitry for supporting wired and/or wireless communications between device 10 and external equipment. For example, control circuitry in device 10 may include wireless communications circuitry such as cellular telephone communications circuitry, wireless local area network communications circuitry, and near-field communications circuitry.

Components 34 may also include input-output circuitry. For example, input-output devices in device 10 may be used to allow data to be supplied to device 10 and to allow data to be provided from device 10 to external devices. Input-output devices may include buttons, joysticks, scrolling wheels, touch pads, key pads, keyboards, microphones, speakers, tone generators, haptic output devices, cameras, light-emitting diodes and other status indicators, data ports, displays, etc. A user can control the operation of device 10 by supplying commands through input-output devices and may receive status information and other output from device 10 using the output resources of input-output devices. The input-output devices may include sensors. The sensors may include capacitive sensors, light-based proximity sensors, magnetic sensors, accelerometers, force sensors, touch sensors, temperature sensors, pressure sensors, inertial measurement units, accelerometers, gyroscopes, compasses, microphones, radio-frequency sensors, three-dimensional image sensors (e.g., structured light sensors with light emitters such as infrared light emitters configured to emit structured light and corresponding infrared image sensors, three-dimensional sensors based on pairs of two-dimensional image sensors, etc.), cameras (e.g., visible light cameras and/or infrared light cameras with or without associated flood illuminators and/or flash systems), light-based position sensors (e.g., lidar sensors), monochrome and/or color ambient light sensors, and other sensors.

If desired, electronic device 10 may include a battery or other energy storage device, connector ports for supporting wired communications with ancillary equipment and for receiving wired power, and other circuitry. In some configurations, device 10 may serve as an accessory and/or may include a wired and/or wireless accessory (e.g., a keyboard, computer mouse, remote control, trackpad, etc.).

Electronic devices (e.g., device 10 of FIG. 1 and/or other devices) may have illuminated one-way mirror structures. These structures may form housing surfaces, surfaces for keys and other movable structures, may form button covers, may form decorative trim, may form logos, may cover trackpad surfaces and/or other surface that have two-dimensional sensors (e.g., two-dimensional capacitive touch sensors, optical sensors, force sensors, etc.), and/or may cover other portions of device 10 (e.g., housing structures forming the exterior surfaces of device 10 that face exterior region 38). Configuration in which one-way mirror structures form logos may sometimes be described herein as an example.

In the example of FIG. 1, a backlit partially reflective mirror structure is used in forming logo 22. Logo 22 may occupy one or more discrete areas on the surface of housing 12. As an example, logo 22 may be formed on rear R of upper housing portion 12A of housing 12. The mirror structure of logo 22 may be formed from one or more thin-film layers. For example, the mirror structure may include a stack of thin-film layers configured to form a partially reflective thin-film interference filter. Backlighting may be provided so that the mirror structure of logo 22 can actively emit light.

The reflective thin-film interference filter of logo 22 (which may sometimes be referred to as a one-way mirror coating or one-way mirror) may be partially reflective to ambient light (e.g., the reflectivity of logo 22 may be 10-40%, at least 5%, at least 10%, at least 20%, at least 30%, at least 40%, less than 99%, less than 75%, less than 45%, less than 35%, less than 25%, less than 15%, or other suitable amount). In some configurations, such as when the reflectivity of logo 22 is 10-40%, the reflectivity is sufficiently high (e.g., at least 10%) to provide logo 22 with a desirable shiny appearance while also being sufficiently low (e.g., less than 40%) to prevent distracting excessively bright specular light reflections from logo 22. The thin-film interference filter or other mirror structures of logo 22 may be configured to exhibit a neutral reflection spectrum, so that logo 22 has a shiny gray appearance or may be configured to exhibit a non-neutral reflection spectrum, so that logo 22 has a shiny colored appearance (e.g., logo 22 may appear to be shiny gold, rose gold, blue, green, red, etc.). In general, the one-way mirror coating of logo 22 may reflect any suitable amount of ambient light and may have any suitable reflection spectrum, any suitable transmission spectrum, and any suitable absorption spectrum.

As shown in FIG. 1, an ambient light source such as ambient light source 24 in the vicinity of device 10 (e.g., in exterior region 38) may produce ambient light 26. Light source 24 may include diffuse and/or specular light sources, may include artificial lighting, natural lighting, etc. Light 26 may serve as exterior illumination for logo 22. Due to the reflectivity of the partially reflective mirror coating of logo 22, 10-40% (or other suitable amount) of ambient light 26 may reflect from the surface of logo 22 and may be viewed by a user such as viewer 28 who is viewing device 10 in direction 30. The mirror-like quality of logo 22 may help visually highlight logo 22 and make logo attractive to users such as viewer 28.

Ambient light 26 that illuminates logo 22 will be partly or completely attenuated by light absorption in logo 22 while passing through logo 22 towards interior region 36. For example, the light transmission through logo 22 (e.g., through the thin-film interference filter and/or other structures used to create mirror reflectivity for logo 22) may be 6-25%, at least 3%, at least 6%, at least 10%, at least 20%, less than 50%, less than 35%, less than 25%, and/or less than 15%. As a result, a reduced amount of ambient light will reach the interior of device 10 and even less of this light will be present after reflecting (specularly or diffusely) from interior structures in device 10 and passing back out through logo 22 to exterior region 38. If, as an example, the light transmission of logo 22 is 10%, less than 1% of the ambient 26 will pass through logo 22 from exterior 38 to interior 36 and then return through logo 22 to exterior 38 from interior 36. Effectively, any passive structures in interior 36 will be insufficiently illuminated by ambient light 26 to be visible to user 28.

To help provide logo 22 with an attractive appearance, the interior side of logo 22 may be provided with active illumination. In configurations in which logo 22 is provided with an active light source such as a backlight unit, the active light source may provide backlight illumination for logo 22 that is visible to user 28 after passing through logo 22. Backlight for logo 22 will be visible to user 28 particularly if ambient light 26 is not placed in bright direct sunlight or other lighting environment in which the magnitude of ambient light 26 is excessive. Because the mirror of logo 22 reflects sufficient ambient light to obscure the interior of device 10 from view by an external viewer while passing backlight illumination from the interior of device 1 to exterior region 38, the mirror of logo 22 may sometimes be referred to as a one-way mirror.

To permit sufficient backlight illumination to pass through logo 22, the reflective thin-film structures of logo 22 (e.g., thin-film layers forming a thin-film interference filter mirror for logo 22) may be configured to transmit 6-25% of the backlight illumination or may exhibit other suitable transmission values for backlight illumination (e.g., at least 5%, at least 6%, at least 10%, at least 20%, less than 80%, less than 30%, less than 25%, and/or less than 20%).

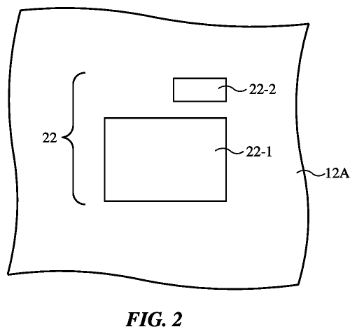

FIG. 2 is a rear view of device 10 in an illustrative configuration in which logo 22 has been formed in housing 12A (e.g., a rear housing wall for housing 12A). Openings in the rear housing wall may receive one or more partially reflective structures forming logo 22. Logo 22 may be formed from a single structure (e.g., a single structure that is surrounded on all sides be portions of housing 12A) or may be formed from two or more separate structures (e.g., separate islands that are each surrounded by portions of housing 12A).

Logo 22 may have any suitable shape such as the shape of a recognizable corporate trademark, etc. In an illustrative configuration, logo 22 may have two or more disjoint portions such as portions 22-1 and 22-2 that are configured, respectively to form an apple shape and an apple leaf shape for the two-part trademarked apple logo associated with products of Apple Inc., of Cupertino, Calif. When device 10 is associated with a different manufacturer, logo 22 may instead be associated with that different manufacturer.

In general, logo 22 may include text, may include rectangles, may include ovals, may include circles, may include shapes with curved and/or straight edges, may be non-textured, may include texture, may be provided with particular logo-specific color and/or pattern of colors, and/or may include other visual features that create a logo. Arrangements in which backlit mirror structures are used for non-logo structures (e.g., icons, key glyphs, decorative trim, text, status indicators, and/or other structures) may also be used, if desired. The configurations described herein in which the backlit mirrors form logos such as logo 22 of FIG. 2 are illustrative.

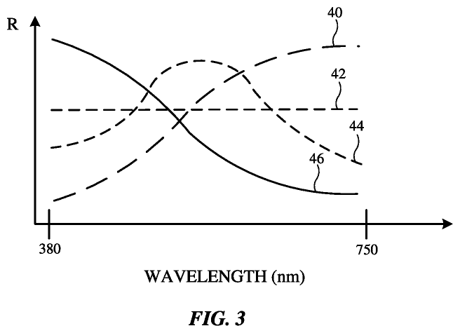

To provide logo 22 with an attractive appearance, the thin-film mirror coating of logo 22 may be configured to exhibit a desired visible-light reflection spectrum (and corresponding desired visible-light transmission and absorption spectrums). Consider, as an example, the illustrative reflection spectrums of FIG. 3. In the graph of FIG. 3, the reflection R of four illustrative partial mirrors for logo 22 have been plotted as a function of wavelength over the visible light spectrum (380 to 750 nm). The example of curve 40 corresponds to a mirror that reflects more red light than blue light and therefore has a reddish color. The example of curve 44 corresponds to a mirror that reflects green light more than red and blue light and therefore is greenish in appearance. The example of curve 46 reflects more blue light than red light and therefore appears to be blueish. These illustrative examples (curves 40, 44, and 46) correspond to mirrors that impart a color cast to reflected ambient light and are therefore sometimes referred to as non-neutral mirrors, colored mirrors, mirrors of non-neutral color, mirrors that exhibit reflection spectrums that vary as a function of visible-light wavelength, or mirrors that exhibit non-neutral reflection spectrums (as examples). In contrast, the example of curve 42 corresponds to a mirror coating with little or no change in reflectivity across the visible light spectrum. Curves such as curve 42 in which reflectivity R varies by less than 10%, less than 5%, or less than 1% (as examples) across the visible light spectrum may sometimes be said to correspond to neutral reflection spectrums as they appear gray with little or no color cast.

When logo 22 is provided with a neutral reflection spectrum, logo 22 will have a shiny gray appearance. When the thin-film interference filter of logo 22 is configured to exhibit a non-neutral reflection spectrum (e.g., a spectrum such as that of curve 40, 44, or 46), logo 22 will have a colored appearance (e.g., when viewed in a direction parallel to the surface normal of logo 22 and/or at off-axis viewing angles). Examples of colors that may be provided for logo 22 include gold, yellow, red, blue (e.g., sky blue or other blue), green, orange, rose gold, and pink. The reflection spectrum of logo 22 may have one or more peaks as a function of wavelength and or may not cause logo 22 to exhibit a noticeable change in appearance as a function of angle of view. The transmission spectrum and absorption spectrum of the thin-film coating of logo 22 may vary in accordance with the variations in the reflection spectrum and/or may have other spectral features. As an example, if logo 22 is configured to exhibit a non-neutral reflection spectrum that reflects more red light than blue light, logo 22 may similarly have a non-neutral transmission spectrum (e.g., a transmission spectrum that passes more blue light than red light). By configuring a backlight for logo 22 to produce a desired spectrum of backlight illumination, logo 22 may be configured to have the same color when illuminated by backlight as when illuminated solely or primarily by reflection of ambient light 26 or logo 22 may be configured to have a first color when illuminated by light 26 and a second color that is different than the first color when illuminated solely or primarily by backlight illumination.

Logo 22 may have one or more supporting structures (sometimes referred to as substrates) such as layers of glass, ceramic, polymer, crystalline material such as sapphire, and/or other transparent members. Thin-film layers may be deposited on these supporting structures using physical vapor deposition (e.g., evaporation and/or sputtering), using chemical vapor deposition, and/or other thin-film deposition techniques. Light sources and other components for providing backlight illumination (sometimes referred to herein as a backlight, backlight unit, or backlight structures) may be formed using light-emitting diodes, lasers, and/or other light-emitting devices. A backlight for logo 22 may be attached to the supporting structures of logo 22 using adhesive and/or other attachment structures and/or a backlight for logo 22 may be separated by supporting structures in logo 22 by an air gap. Illustrative arrangements in which backlight structures for logo 22 are attached to the inner side of logo 22 by adhesive may sometimes be described herein as an example.

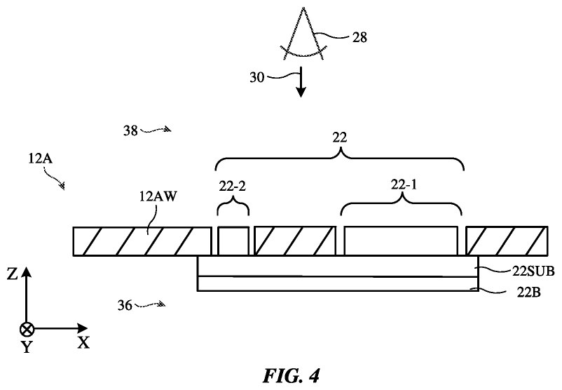

FIG. 4 is a cross-sectional side view of logo 22 in an illustrative configuration in which logo 22 has first and second portions that protrude through corresponding first and second openings in housing wall 12AW of housing 12A. As shown in FIG. 4, portion 22-1 of logo 22 may protrude through a larger opening in wall 12AW than portion 22-2. The protruding portions of logo 22 may be provided with separate substrates that are attached to a common substrate (see, e.g., substrate 22SUB) or may be formed from locally thickened portions of a common substrate. The thickness of the portions of logo 22 that are received within the openings of housing wall 12AW may, as an example, be matched to that of wall 12AW. Backlight 22B may be attached to the inner side of logo 22 or may be separated from the other structures of logo 22 by an air gap.

The structures of logo 22 (e.g., the protruding logo structures that are received within openings in wall 12AW, the structures of common substrate 22SUB, and/or the structures of backlight 22B) may each include one or more structural layers (substrate layers), one or more adhesive layers, one or more ink layers, and/or one or more thin-film layers (e.g., thin-film layers for forming a mirror coating and/or other functional thin-film layers such as antismudge layers, antireflection coatings, anti-scratch layers, antistatic layers, etc.)

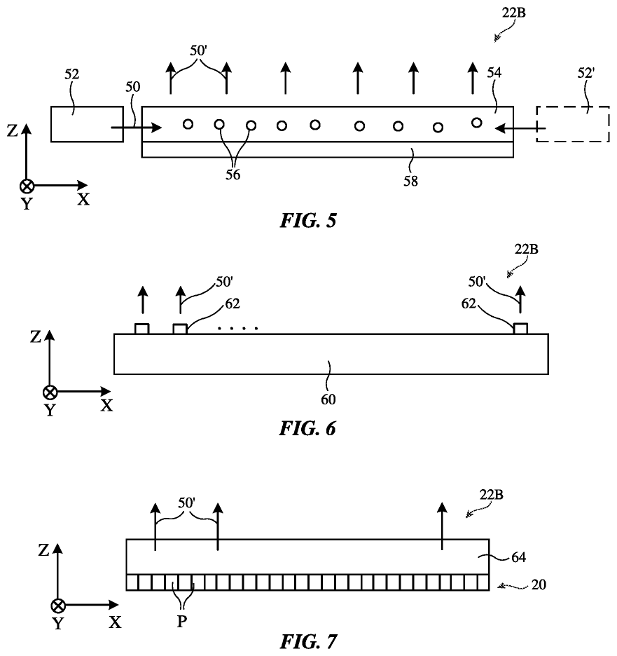

FIGS. 5, 6, and 7 are cross-sectional side views of illustrative backlights for logo 22. In the example of FIG. 5, backlight 22B is an edge lit light guide backlight. As shown in FIG. 5, light 50 may be emitted by light source 52 into an adjacent edge of light guide layer 54. Light guide layer 54 may be a flexible polymer film or other transparent layer of material that guides light 50 across backlight 22B (e.g., laterally within the X-Y plane) in accordance with the principal of total internal reflection. Light-scattering structure 56 scatter light 50 out of layer 54 to form backlight illumination 50′. Light-scattering structures 56 may be pits, grooves, or other recesses, may be bumps, ridges, or other protrusions associated with layer 54, and/or may include light-scattering particles in layer 54 such as voids or embedded dielectric particles formed, for example, of inorganic dielectric such as titanium dioxide or other metal oxide exhibiting a refractive index that varies from that of the polymer of layer 54 in which the particles are embedded. Light that is scattered inwardly (in the -Z direction of FIG. 5) may be reflected in the outward direction by reflector 58 (e.g., a film with a reflective layer formed from a reflective thin-film interference filter formed from a stack of dielectric layers of alternating refractive index, shiny white polymer, and/or a reflective metal thin-film layer on a polymer substrate layer). Scattered light 50′ may serve as backlight illumination for logo 22 and may pass through the partially reflective mirror structures in logo 22 to be viewed by a user.

If desired, the density of light-scatting structures 56 in backlight 22B may be varied (e.g., increased) as a function of distance across light guide layer 54 away from light source 52 to help produce spatially uniform backlight illumination 50′. More than one light source may be provided along the edge(s) of light guide layer 54. For example, there may be one or more light sources along the left edge of layer 54 and one more additional light sources 52′ along the opposing right edge of layer 54. Light sources 52 and/or 52′ may be formed from laser diodes, light-emitting diodes, or other light-emitting devices and may produce white light, colored light (e.g., yellow light, blue light, red light, green light, light characterized by a spectrum with one or more peaks, etc.). If desired, multiple different light-emitting diodes, lasers, or other light-emitting components of multiple colors may be include in light sources 52 and/or 52′, so that control circuitry in device 10 can dynamically alter the mix of emitted light colors from these devices and thereby adjust the color of illumination 50′.

In the example of FIG. 6, backlight 22B has a substrate such as substrate 60 (e.g., a printed circuit) onto which a two-dimensional array of light-emitting devices 62 (e.g., lasers, light-emitting diodes, etc.) have been mounted. Devices 62 may be arranged in a grid pattern with a center-to-center spacing of at least 100 microns, at least 250 microns, at least 1 mm, at least 2 mm, less than 50 mm, less than 30 mm, less than 15 mm, less than 10 mm, less than 7 mm, less than 4 mm, less than 2 mm, less than 1 mm, less than 500 microns, less than 300 microns, or less than 150 microns (as examples). Light-emitting devices 62 may be controlled as a group (e.g., to adjust backlight illumination 50′ globally) and/or may be individually controlled (e.g., to produce time-varying even illumination, to produce areas of even and/or uneven lighting across logo 22, to produce lighting with a desired color and/or time-varying colors, to produce text or graphics, to produce adjustable icons, to produce adjustable glyphs for keyboard keys, to produce moving illuminated abstract light patterns to visually confirm to a user that device 10 is recognizing and responding to voice commands or other input, etc.).

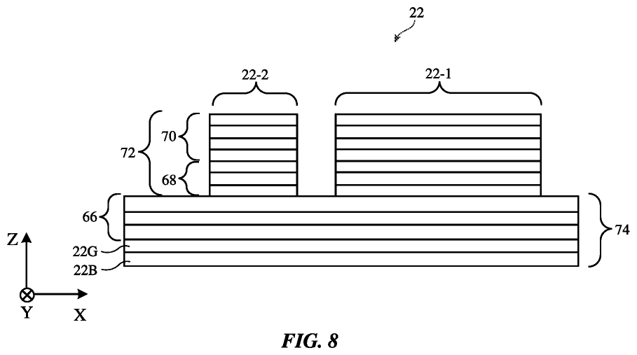

If desired, backlight 22B may use light leakage from display 20 or other component(s) to produce backlight illumination 50′. Consider, as an example, the cross-sectional side view of display 20 of FIG. 7. As shown in FIG. 7, display 20 may include an array of pixels P for producing an image that is viewed by a viewer facing display 20. Display 20 may have a transparent substrate such as substrate 64. During operation of display 20, a backlight unit in display 20 and/or pixels P in display 20 may emit light. Image light associated with display 20 propagates in the −Z direction of FIG. 7 so that a user may view an image on display 20. Some of the emitted light (e.g., stray light and/or light that passes through a portion of a reflector such as reflector 58 of FIG. 5 that has locally reduced reflectivity) exits the rear of display 20. This illumination (illumination 50′ of FIG. 7) may travel in the opposite direction from the image light emitted by pixels P that is associated with displayed images on display 20. By forming logo 20 at the rear of display 20 of FIG. 7, display 20 may serve as backlight 22B (e.g., light emitted from the rear of display 20 may serve as backlight illumination 50′ for logo 22).

FIG. 8 is a cross-sectional side view of an illustrative logo of the type that may be provided with backlight illumination 50′ from backlight 22B (e.g., a backlight unit such as one of backlights 22B of FIGS. 5, 6, and 7 or other suitable backlight structures). Logo 22 may have one or more protruding portions such as portions 22-1 and 22-2. The protruding portions may be formed from protruding stacks of layers 72 on supporting layers 74. Supporting layers 74 may include, for example, one or more structural layers that serve as a common supporting substrate for portions 22-1 and 22-2. As described in connection with portions 22-1 and 22-2 of FIG. 4, portions 22-1 and 22-1 of FIG. 8 may have a thickness that is matched to the thickness of rear housing wall 12AW or other housing structure having openings with a size and shape matched to the size and shape of portions 22-1 and 22-2 (e.g., wall 12AW may have openings with footprints (outlines viewed in the −Z direction) that match corresponding footprints for portions 22-1 and 22-2.

Layers 74 may include backlight 22B. Backlight 22B may be attached to other portions of layers 74 such as layers 66 using a layer of adhesive 22G or adhesive 22G may be replaced by an air gap.

Layers 66 may include one or more polymer layers (e.g., a polymer layer with embedded fibers such as a fiberglass layer of about 0.2-1.0 mm in thickness that serves as a light diffusing layer and structural support for portions 22-1 and 22-2), may include adhesive layer(s) to attach the fiberglass layer or other layer(s) to layers 74, may include one or more layers of colored ink or other structures that create desired spatially uniform or non-uniform color across backlight 22B, and/or may include one or more other layers of material such as transparent protective layers formed from cured polymer, etc.

In an illustrative configuration, layers 66 may include three layers. The uppermost layer may be a polymer plate (e.g., a polycarbonate layer or other polymer layer) that serves as a structural support (substrate). This layer may have a thickness of 0.15 mm, at least 0.5 mm, at least 0.1 mm, at least 0.15 mm, less than 0.3 mm, less than 0.25 mm, less than 0.2 mm, or less than 0.15 mm (as examples). If desired, a glass layer or other transparent plate may be used as a substrate in addition to or instead of using the polymer plate to provide structural support for logo 22. The side of the polymer plate that faces backlight 22B may be coated with a layer of ink. The layer of ink may include ink of neutral colors (e.g., gray ink, white ink, and/or black ink) and/or may include ink of non-neutral colors (yellow, blue, red, green, etc.). This ink may be protected using a transparent polymer layer (e.g., the lowermost of layers 66 may be a varnish layer that coats the ink and faces backlight 22B). The ink layer may be uniform across logo 22 or may have gradients and/or patches of varying color. For example, patches of different colors may be used to provide logo 22 with backlight having a desired pattern of colors. The color of the ink on the polymer plate and the transmission spectrum of the thin-film interference filter in logo 22 may affect the color of the backlight illumination exiting logo 22.

This illustrative arrangement for layers 66 may be used with any suitable combination of layers 74. In an illustrative configuration, layers 74 include first protruding layers 68 and second protruding layers 70, which may have the same footprint as layers 68. First protruding layers 68 may include, for example, first and second layers of adhesive (e.g., ultraviolet-light cured polymer or other glue) and an additional polymer layer such as a layer of acrylic with a thickness of 0.38 mm, at least 0.2 mm, less than 0.6 mm, or other suitable thickness. The additional polymer layer may serve be used to provide logo 22 with additional strength. The additional polymer layer may be sandwiched between the first and second layers of adhesive. The first layer of adhesive may attach the additional polymer layer to layers 66. The second layer of adhesive may attach the additional polymer layer to layers 70.

Layers 70 may include a transparent substrate layer such as a substrate layer of polyethylene terephthalate or other polymer. This substrate layer may have a thickness of at least 0.05 mm, at least 0.1 mm, 0.125 mm, less than 0.3 mm, or other suitable thickness and may help provide structural support for thin-film layers in layers 70. An antiscratch coating may be formed on the outer surface of the substrate layer. The outermost layer in layers 70 may, for example, include a thin-film hard coat layer (e.g., a layer of silicon nitride or other scratch-resistance inorganic thin-film coating layer that helps protect the exposed outer surface of logo 22 from scratches). One or more thin-film layers may be formed as a thin-film coating on the inner surface of the substrate layer. An optional protective coating on the inner surface of the thin-film coating facing layers 68 may provide additional protection. This protective coating may be, for example, a layer of transparent black polymer (e.g., black varnish) or other protective polymer that helps to control light transmission and protect the thin-film coating in layers 70 from underlying materials in layers 68.

The thin-film coating on the inner surface of the substrate layer of layers 70 may be configured to provide logo 22 with desired optical properties (e.g., desired spectrums associated with visible light transmission, absorption, and reflection). In an illustrative arrangement, the thin-film coating may include one or more light-absorbing layers such as one or more metal layers (e.g., one or more thin-film layers of silver, nickel, etc.). Thin-film metal layer(s) in the coating may help absorb light and thereby reduce light transmission to a desired level of partial transparency, ensuring that that logo 20 exhibits a one-way mirror effect and avoiding the creation of excessive reflectivity for ambient light. If desired, one or more thin-film layers (e.g., dielectric layers, metal layers, etc.) in the coating may have thicknesses and refractive index values that create a thin-film interference filter with desired optical properties (e.g., desired spectrums associated with transmission, absorption, and reflection across visible light wavelengths). Single-material coatings formed only of a single metal (e.g., silver, nickel, etc.) may also be used to form the partial mirror coating of layers 70, if desired.

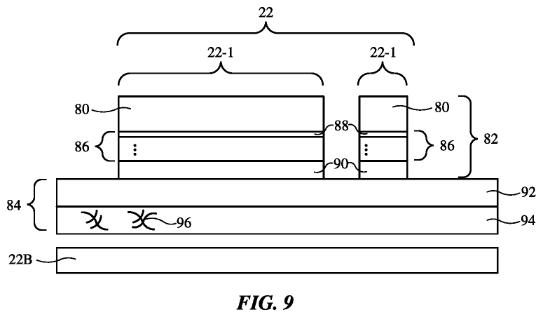

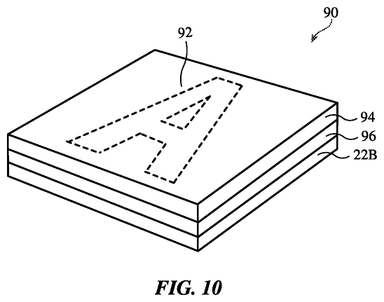

FIG. 9 is a cross-sectional side view of logo 22 in an illustrative configuration in which logo 22 contains a stack of thin-film layers configured to form a thin-film interference filter that serves as a mirror coating with desired optical properties (e.g., desired neutral or non-neutral spectrums associated with visible light transmission, absorption, and reflection). As shown in FIG. 9, the outwardly facing portion of logo 22 may contain a structural substrate layer such as a layer of glass, polymer, or other transparent substrate material (e.g., substrate layer 80). The outer surface of layer 80 may be coated with an antiscratch layer, if desired.

Thin-film filter 86 may be formed from a stack of thin-film layers 88 on the inner surface of substrate layer 80. In an illustrative configuration, layers 88 include one or more metal layers such as layers of titanium or other metals to help reduce light transmission for filter 86. Filter 86 may also include thin-film dielectric layers (e.g., thin-film inorganic dielectric layers such as metal oxide layers).

The thicknesses and refractive index values of layers 88 may be selected to provide logo 22 with a desired reflectivity, transmission, and absorption across visible light wavelengths. In one illustrative arrangement, filter 86 has five layers. The first (outermost) layer is a 2 nm titanium layer, the second layer is an 88 nm aluminum oxide layer, the third layer is a 4 nm titanium layer, the fourth layer is a 119 nm aluminum oxide layer, and the fifth (and innermost) thin-film layer 88 is a 4.2 nm titanium layer. This arrangement and/or other arrangements may be used to provide logo 22 with a desired amount of light reflection (so that logo 22 is shiny) while limiting light transmission so that logo 22 serves as a one-way mirror that hides internal structures from view from exterior region 38. Ink layer 90 may be provided between layers 88 and support layer 84 to help adjust the color and other attributes of the appearance of logo 22. Layer 90 may be uniform across the X and Y dimensions of logo 22, may be provided with gradients (e.g., to change smoothly from one color such as red to another color such as blue), and/or may be characterized by patches or other areas that each have a different associated color and/or opacity). As an example, one area of layer 90 may be black, another may be light red, another may be dark red, another may be blue, and another area may have a color gradient that changes smoothly from yellow to red, and a fourth area may have a neutral gray tone that changes smoothly from light gray to dark gray as a function of distance across logo 22.

Portions 22-1 and 22-2 may protrude from separate areas of a common support layer such as layer 84. Layer 84 may include a common substrate layer such as layer 94 that is attached to portions 22-1 and 22-2 using adhesive layer 92. The uncovered portions of adhesive 92 of FIG. 9 may help attach layer 84 to the inside surface of housing wall 12AW. In an illustrative configuration, layer 94 is formed from polymer and has embedded structures such as fibers 96 (e.g., layer 94 may be a fiberglass substrate layer). The use of fiberglass to form layer 94 may help enhance strength while retaining a desired amount of light transmission for backlight illumination produced by backlight 22B. The fibers in the fiberglass may also help diffuse the backlight illumination provided by backlight 22B. Backlight 22B may be separated from layer 94 by an air gap or may be coupled to layer 94 by a layer of adhesive.

As shown in FIG. 10, items other than logos may be provided with partially reflective coatings such as backlit colored partially reflective coatings. Consider, as an example, key 90 of FIG. 10. Key 90 may be part of a keyboard of similar keys arranged in an array to form keyboard 16 of FIG. 1. Each key may have a backlight 22B or may overlap a portion of a shared backlight. The backlight may be formed from a single light-emitting diode or, if desired, may be pixelated (see, e.g., backlight 22B of FIG. 6). By using an adjustable backlight such as a pixelated backlight, the shape of illuminated glyph 92 can be adjusted dynamically. The light emitted by the portion of key 90 associated with glyph 92 may, as an example, be adjusted to form different alphanumeric characters for an adjustable keyboard (e.g., various letters and/or numbers), may be adjusted to form an icon, may be adjusted to form a text label, etc.

Backlight arrangements in which each key has a trim that is illuminated or that has globally adjustable backlight illumination may be used, if desired. Backlight illumination from backlight 22B may pass through one or more overlapping layers such as layers 94 and 96. Layer 94 and/or layer 96 may include a transparent layer of glass, polymer, or other material that serves as a substrate layer. Thin-film layers of metal, dielectric, and/or other materials may also be included in layer 94 and/or layer 96 to serve as a mirror coating (e.g., a mirror coating on the substrate layer that is partially reflective and has a desired neutral or non-neutral color). In one illustrative configuration, layer 94 includes a substrate layer and layer 96 includes a mirror coating. In another illustrative configuration, layer 94 is a coating layer that is formed on a substrate layer in layer 96.

The thin-film layers of the mirror coating may provide key 90 with a desired mirror reflectivity and may, in general, be used to provide key 90 with desired optical characteristics (e.g., visible spectrums for transmission, absorption, and reflection) that give rise to a desired neutral or non-neutral color for key 90 (e.g., a non-neutral or neutral color for key 90 both when illuminated by backlight and when illuminated by ambient light). Optional ink (e.g., patterned ink) may be included in key 90 to help adjust the appearance of key 90. If desired, other portions of device 10 (e.g., trackpads, buttons, housing walls, and/or other portions of device 10 that are formed from glass, polymer, crystalline material such as sapphire, and/or other supporting materials) may, if desired, be provided with backlight 22B and a partially reflective one-way mirror coating with a desired appearance (e.g., desired neutral or non-neutral color, desired visible light spectrums for transmission, reflection, and absorption, etc.). The use of partially reflective coatings on a logo received within logo-shaped opening in housing 12A of device 10 is illustrative.

As described above, one aspect of the present technology is the gathering and use of information such as information from input-output devices. The present disclosure contemplates that in some instances, data may be gathered that includes personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, username, password, biometric information, or any other identifying or personal information.

The present disclosure recognizes that the use of such personal information, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the United States, collection of or access to certain health data may be governed by federal and/or state laws, such as the Health Insurance Portability and Accountability Act (HIPAA), whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, the present technology can be configured to allow users to select to “opt in” or “opt out” of participation in the collection of personal information data during registration for services or anytime thereafter. In another example, users can select not to provide certain types of user data. In yet another example, users can select to limit the length of time user-specific data is maintained. In addition to providing “opt in” and “opt out” options, the present disclosure contemplates providing notifications relating to the access or use of personal information. For instance, a user may be notified upon downloading an application (“app”) that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of information that may include personal information data to implement one or more various disclosed embodiments, the present disclosure also contemplates that the various embodiments can also be implemented without the need for accessing personal information data. That is, the various embodiments of the present technology are not rendered inoperable due to the lack of all or a portion of such personal information data.

The foregoing is merely illustrative and various modifications can be made to the described embodiments. The foregoing embodiments may be implemented individually or in any combination.

What is claimed is:

1. An electronic device, comprising:
a housing having a housing wall with an opening; and
a partially transparent backlit mirror in the opening, wherein the partially transparent backlit mirror has a substrate, a partially reflective mirror coating on the substrate, and a backlight that is configured to provide backlight illumination that passes through the substrate and the partially reflective mirror coating.

2. The electronic device defined in claim 1 wherein the partially reflective mirror coating comprises a thin-film metal layer.

3. The electronic device defined in claim 2 further comprising a layer of ink between the thin-film metal layer and the backlight.

4. The electronic device defined in claim 2 wherein the backlight comprises at least one light-emitting diode.

5. The electronic device defined in claim 4 wherein the backlight comprises a light guide layer configured to receive light from the light-emitting diode and configured to scatter the light from the light-emitting diode out of the light guide layer to form the backlight illumination.

6. The electronic device defined in claim 2 wherein the backlight comprises a substrate layer that is overlapped by the partially reflective mirror coating and comprises a two-dimensional array of light-emitting diodes on the substrate that are configured to provide the backlight illumination.

7. The electronic device defined in claim 2 further comprising a display with pixels configured to display images, wherein the backlight is formed from part of the display.

8. The electronic device defined in claim 1 wherein the partially reflective mirror coating has a non-neutral color.

9. The electronic device defined in claim 1 wherein the partially reflective mirror coating comprises a stack of thin-film layers including multiple metal layers and multiple dielectric layers.

10. The electronic device defined in claim 1 wherein the partially reflective mirror coating comprises a thin-film interference filter formed from a plurality of thin-film layers.

11. The electronic device defined in claim 1 wherein the partially reflective mirror coating is configured to exhibit a reflectivity of 10-40%.

12. The electronic device defined in claim 11 wherein the partially reflective mirror coating exhibits a non-uniform visible light reflection spectrum.

13. The electronic device defined in claim 1 wherein the opening is configured to form at least part of a logo.

14. The electronic device defined in claim 1 wherein the partially reflective mirror coating has a reflectivity of at least 10% and a light transmission of less than 25%.

15. The electronic device defined in claim 1 wherein the substrate comprises a glass layer and wherein the partially reflective mirror coating is between the glass layer and the backlight.

16. The electronic device defined in claim 15 further comprising a layer of fiberglass between the backlight and the glass layer.

17. An electronic device, comprising:
a housing having at least first and second openings; and
a backlit partially reflective mirror structure having first and second separate protrusions supported on a common substrate, wherein the first protrusion is received within the first opening and the second protrusion is received within the second opening.

18. The electronic device defined in claim 17 wherein the backlit partially reflective mirror structure has a partially reflective mirror coating with a reflectivity of 10-40% and wherein the backlight has at least one light-emitting diode configured to provide backlight illumination that passes through the partially reflective mirror coating.

19. The electronic device defined in claim 18 wherein the backlit partially reflective mirror coating has a visible light reflection that varies as a function of wavelength to provide the backlit partially reflective mirror coating with a color under ambient light illumination.

20. The electronic device defined in claim 19 wherein the backlit partially reflective mirror coating comprises a thin-film interference filter having a stack of thin-film layers.

21. The electronic device defined in claim 20 wherein the stack of thin-film layers includes multiple thin-film metal layers.

22. The electronic device defined in claim 21 wherein the first and second openings are configured to form a logo and wherein the stack of thin-film layers is configured to exhibit a transmission of less than 25% for at least one visible light wavelength.

23. An electronic device, comprising:
a housing having first and second portions configured to rotate relative to each other, wherein the first portion has a keyboard and wherein the second portion has a display and has a housing wall with an opening; and
a partially reflective mirror in the opening that has a non-neutral color.

24. The electronic device defined in claim 23 further comprising a backlight with at least one light-emitting device configured to emit backlight illumination that passes through the partially reflective mirror.

25. The electronic device defined in claim 24 wherein the first and second portions are configured to form a logo and wherein the partially reflective mirror has a thin-film coating with a reflectivity of 10-40%.

26. The electronic device defined in claim 25 wherein the non-neutral color is a color selected from the group consisting of gold, blue, red, and green and wherein the partially reflective mirror has a stack of thin-film layers including at least one dielectric thin-film layer and at least one metal thin-film layer.
